(19) United States
(12) Patent Application Publication
(10) Pub. No.: US 2024/0392433 A1
(43) Pub. Date: Nov. 28, 2024

(54) Homoleptic Bismuth Precursors For Depositing Bismuth Oxide Containing Thin Films

(71) Applicant: Versum Materials US, LLC, Tempe, AZ (US)

(72) Inventors: Sergei V. Ivanov, Schnecksville, PA (US); Michael T. Savo, Bethlehem, PA (US); Jason P. Coyle, San Jose, CA (US)

(21) Appl. No.: 18/704,551

(22) PCT Filed: Dec. 15, 2022
(86) PCT No.: PCT/US2022/081635

§ 371 Date: Apr. 25, 2024

Related U.S. Application Data
(60) Provisional application No. 63/265,796, filed on Dec. 21, 2021.

(51) Int. Cl. C23C 16/30; C23C 16/44; C23C 16/455; H01L 21/3205

(52) U.S. Cl. CPC C23C 16/30; C23C 16/4408; C23C 16/45553; H01L 21/32051

(57) ABSTRACT

The disclosed and claimed subject matter relates to (i) homoleptic precursors of the formula Bi(Ar)3 where Ar is one or more a bulky alkyl group selected from an iso-propyl group, a sec-butyl group, an iso-butyl group, a neo-pentyl group, a sec-pentyl group and an iso-pentyl group and (ii) the use thereof as precursors for deposition of metal-containing films.

### BACKGROUND

### Field

The disclosed and claimed subject matter relates to (i) homoleptic precursors of the formula Bi(Ar)₃ where Ar is a bulky alkyl group selected from an iso-propyl group, a sec-butyl group, an iso-butyl group, a neo-pentyl group, a sec-pentyl group and an iso-pentyl group and (ii) the use thereof as precursors for deposition of metal-containing films.

### Related Art

Metal-containing films are used in semiconductor and electronics applications. Chemical Vapor Deposition (CVD) and Atomic Layer Deposition (ALD) have been applied as the main deposition techniques for producing thin films for semiconductor devices. These methods enable the achievement of conformal films (metal, metal oxide, metal nitride, metal silicide, and the like) through chemical reactions of metal-containing compounds (precursors). The chemical reactions occur on surfaces which may include metals, metal oxides, metal nitrides, metal silicides, and other surfaces. In CVD and ALD, the precursor molecule plays a critical role in achieving high quality films with high conformality and low impurities. The temperature of the substrate in CVD and ALD processes is an important consideration in selecting a precursor molecule. Higher substrate temperatures, in the range of 150 to 500 degrees Celsius (° C.), promote a higher film growth rate. The preferred precursor molecules must be stable in this temperature range. The preferred precursor is capable of being delivered to the reaction vessel in a liquid phase. Liquid phase delivery of precursors generally provides a more uniform delivery of the precursor to the reaction vessel than solid phase precursors.

CVD and ALD processes are increasingly used as they have the advantages of enhanced compositional control, high film uniformity, and effective control of doping. Moreover, CVD and ALD processes provide excellent conformal step coverage on highly non-planar geometries associated with modern microelectronic devices.

CVD is a chemical process whereby precursors are used to form a thin film on a substrate surface. In a typical CVD process, the precursors are passed over the surface of a substrate (e.g., a wafer) in a low pressure or ambient pressure reaction chamber. The precursors react and/or decompose on the substrate surface creating a thin film of deposited material. Plasma can be used to assist in reaction of a precursor or for improvement of material properties. Volatile by-products are removed by gas flow through the reaction chamber. The deposited film thickness can be difficult to control because it depends on coordination of many parameters such as temperature, pressure, gas flow volumes and uniformity, chemical depletion effects, and time.

ALD is a chemical method for the deposition of thin films. It is a self-limiting, sequential, unique film growth technique based on surface reactions that can provide precise thickness control and deposit conformal thin films of materials provided by precursors onto surfaces substrates of varying compositions. In ALD, the precursors are separated during the reaction. The first precursor is passed over the substrate surface producing a monolayer on the substrate surface. Any excess unreacted precursor is pumped out of the reaction chamber. A second precursor or co-reactant is then passed over the substrate surface and reacts with the first precursor, forming a second monolayer of film over the first-formed monolayer of film on the substrate surface. Plasma may be used to assist with reaction of a precursor or co-reactant or for improvement in materials quality. This cycle is repeated to create a film of desired thickness.

Thin films, and in particular thin metal-containing films, have a variety of important applications, such as in nanotechnology and the fabrication of semiconductor devices. Examples of such applications include capacitor electrodes, gate electrodes, adhesive diffusion barriers and integrated circuits.

Trimethyl bismuth (BiMe₃) and triphenyl bismuth (BiPh₃) are volatile, homoleptic bismuth compounds with some degree of utility as ALD precursors. Despite this, they are not practical options for ALD applications. Among other things, trimethyl bismuth is difficult to purify and deliver in a safe manner. See Adv. Mater. Opt. Electron., 10, 193 (2000); Integr. Ferroelectr., 45, 215 (2002). Trimethyl bismuth is also a pyrophoric liquid that has been stabilized with dioxane to prevent explosion when used as a bismuth source in MOCVD applications. While trimethyl bismuth and triethylbismuth were used for MOCVD applications, there are not practical options for atomic layer deposition due to very low thermal stability. See Chem. Vap. Deposition, 19, 61-67 (2013). While triphenyl bismuth has good thermal stability and it was used for atomic layer deposition, triphenyl bismuth is a solid with very low vapor pressure. See Thin Solid Films, 622, 65-70 (2017) and Chem. Vap. Deposition, 6, 139-145 (2000). These disadvantages are problematic for high volume manufacturing of semiconductor devices and therefore preclude their use in applications that require a high degree of control over conformality and precursor flux.

Cone angles have been theoretically calculated for a hypothetical Bi(Np)₃ complex. See Koordinatsyonnaya Khimiya, 11(9), 1171-1178 (1985). This reference does not report a synthesis or characterization of this material.

Aside from homoleptic alkyl and aryl compounds for consideration as bismuth precursors, other bismuth compounds are known for use in ALD in a limited capacity as follows:

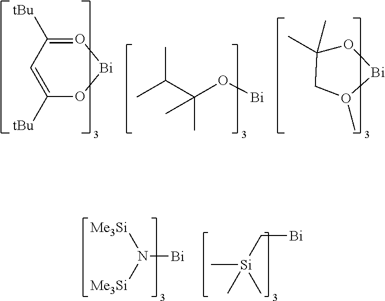

See Coord. Chem. Rev., 251, 974-1006 (2007); Coord. Chem. Rev., 257, 3297-3322 (2013); Organomet. Chem., 42, 1-53 (2019). For example, bismuth tris(2,2,6,6-tetramethyl-3,5-heptanedionate) has a high molecular weight and requires a high source temperature for precursor delivery. This precursor has a narrow ALD window of 275-300° C. At lower deposition temperatures precursor condensation was observed while at higher temperatures the growth rate per cycle diminished. See J. Phys. Chem. C, 116, 3449-3456 (2012)).

Bismuth alkoxides compounds are relatively easy to prepare and are volatile. ALD of Bi₂O₃ employing a bismuth alkoxide precursor was demonstrated on substrates heated below 200° C. However, at temperatures above 200° C., and specifically closer to 300° C., it is unlikely that bismuth alkoxides would be suitable for ALD of Bi₂O₃ due to a high rate of thermal decomposition. See J. Vac. Sci. Technol. A., 32(1), 01A113 (2014).

Bismuth compounds containing silicon are problematic for ozone-ALD processes. It has been shown that the precursors tris(hexamethyldisilazane)bismuth and tris(trimethylsilylmethyl)bismuth deposit bismuth silicate thin films in ozone-based ALD. See Chem. Vap. Deposition, 11, 362-367 (2005).

Uses of bismuth compounds are also described in: Thin Solid Films, 622, 65-70 (2017); U.S. Pat. Nos. 5,902,639; 7,618,681; 6,916,944; 10,186,570; and U.S. Patent Application Publication No. 2010/0279011. None of these or the above references describe viable ALD of Bi₂O₃ by via processes employing BiNp₃ as disclosed and claimed herein.

### SUMMARY

The disclosed and claimed subject matter relates to (i) homoleptic precursors of the formula Bi(Ar)₃ where Ar is a bulky alkyl group selected from an iso-propyl group, a sec-butyl group, an iso-butyl group, a neo-pentyl group, a sec-pentyl group and an iso-pentyl group and (ii) the use thereof as precursors for deposition of bismuth oxide thin films under high through-put process parameters. Additionally, the process parameters are compatible with current state of the art methods for depositing high quality metal oxide thin films in semiconductor manufacturing. Therefore, mixed metal oxide thin films are achievable with the invented method and compositions. When two or more processes are compatible, both processes can be run consecutively on a single piece of equipment without requiring downtime to switch between parameters (e.g., changing the substrate temperature). High through-put process parameters for atomic layer deposition target a short cycle time. The precursor compositions of this invention enable high precursor flux, short precursor purge times, self-limiting growth behavior at substrate temperatures between about 200° C. and about 400° C. and, in some embodiments, the use of ozone as the second precursor.

In one preferred embodiment, homoleptic precursors of the formula Bi(Ar)₃ is tri(neo-pentyl)bismuth (“BiNp₃”):

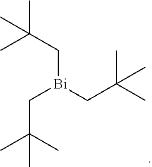

In one preferred embodiment, homoleptic precursors of the formula Bi(Ar)₃ is tri(sec-pentyl)bismuth.

In one preferred embodiment, homoleptic precursors of the formula Bi(Ar)₃ is tri(iso-pentyl)bismuth.

In one embodiment, homoleptic precursors of the formula Bi(Ar)₃ is tri(iso-propyl)bismuth.

In one embodiment, homoleptic precursors of the formula Bi(Ar)₃ is tri(sec-butyl)bismuth.

In one embodiment, homoleptic precursors of the formula Bi(Ar)₃ is tri(iso-butyl)bismuth.

In another embodiment, the disclosed and claimed subject matter includes the use of the above-described heteroleptic bismuth compounds in ALD deposition processes.

### DETAILED DESCRIPTION

All references, including publications, patent applications, and patents, cited herein are hereby incorporated by reference to the same extent as if each reference were individually and specifically indicated to be incorporated by reference and were set forth in its entirety herein.

The use of the terms “a” and “an” and “the” and similar referents in the context of describing the disclosed and claimed subject matter (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the disclosed and claimed subject matter and does not pose a limitation on the scope of the disclosed and claimed subject matter unless otherwise claimed. No language in the specification should be construed as indicating any non-claimed element as essential to the practice of the disclosed and claimed subject matter. The use of the term “comprising” or “including” in the specification and the claims includes the narrower language of “consisting essentially of” and “consisting of.”

Embodiments of the disclosed and claimed subject matter are described herein, including the best mode known to the inventors for carrying out the disclosed and claimed subject matter. Variations of those embodiments may become apparent to those of ordinary skill in the art upon reading the foregoing description. The inventors expect skilled artisans to employ such variations as appropriate, and the inventors intend for the disclosed and claimed subject matter to be practiced otherwise than as specifically described herein. Accordingly, the disclosed and claimed subject matter includes all modifications and equivalents of the subject matter recited in the claims appended hereto as permitted by applicable law. Moreover, any combination of the above-described elements in all possible variations thereof is encompassed by the disclosed and claimed subject matter unless otherwise indicated herein or otherwise clearly contradicted by context.

For ease of reference, “microelectronic device” or “semiconductor device” corresponds to semiconductor wafers having integrated circuits, memory, and other electronic structures fabricated thereon, and flat panel displays, phase change memory devices, solar panels and other products including solar substrates, photovoltaics, and microelectromechanical systems (MEMS), manufactured for use in microelectronic, integrated circuit, or computer chip applications. Solar substrates include, but are not limited to, silicon, amorphous silicon, polycrystalline silicon, monocrystalline silicon, CdTe, copper indium selenide, copper indium sulfide, and gallium arsenide on gallium. The solar substrates may be doped or undoped. It is to be understood that the term “microelectronic device” or “semiconductor device” is not meant to be limiting in any way and includes any substrate that will eventually become a microelectronic device or microelectronic assembly.

As defined herein, the term “barrier material” corresponds to any material used in the art to seal the metal lines, e.g., copper interconnects, to minimize the diffusion of said metal, e.g., copper, into the dielectric material. Preferred barrier layer materials include tantalum, titanium, ruthenium, hafnium, and other refractory metals and their nitrides and silicides.

“Substantially free” is defined herein as less than 0.001 wt. %. “Substantially free” also includes 0.000 wt. %. The term “free of” means 0.000 wt. %. As used herein, “about” or “approximately” are intended to correspond to within ±5% of the stated value. The term “substantially free” can also be related to halide ions (or halides) such as, for example, chlorides (i.e., chloride-containing species such as HCl or bismuth compounds having at least one Bi—Cl bond) and fluorides, bromides and iodides as impurities in the bismuth compounds having formula of Bi(Ar)₃. The level of halide impurities is less than 5 ppm (by weight) measured by ion chromatography (IC), preferably less than 3 ppm measured by IC, and more preferably less than 1 ppm measured by IC, and most preferably 0 ppm measured by IC. In addition, the term “substantially free” can also be referred to substantially free of metal ions such as, Li⁺, Na⁺, K⁺, Mg²⁺, Ca²⁺, Al³⁺, Fe²⁺, Fe³⁺, Ni²⁺ and Cr³⁺ as impurities in the bismuth compounds having formula of Bi(Ar)₃. As used herein, the term “substantially free” as it relates to Li, Na, K, Mg, Ca, Al, Fe, Ni and Cr each of which metal is less than 5 ppm (by weight), preferably less than 3 ppm, and more preferably less than 1 ppm, and most preferably 0.1 ppm as measured by ICP-MS or other analytical method for measuring metals.

In all such compositions, wherein specific components of the composition are discussed in reference to weight percentage (or “weight %”) ranges including a zero lower limit, it will be understood that such components may be present or absent in various specific embodiments of the composition, and that in instances where such components are present, they may be present at concentrations as low as 0.001 weight percent, based on the total weight of the composition in which such components are employed. Note all percentages of the components are weight percentages and are based on the total weight of the composition, that is, 100%. Any reference to “one or more” or “at least one” includes “two or more” and “three or more” and so on.

Where applicable, all weight percents unless otherwise indicated are “neat” meaning that they do not include the aqueous solution in which they are present when added to the composition. For example, “neat” refers to the weight % amount of an undiluted acid or other material (i.e., the inclusion 100 g of 85% phosphoric acid constitutes 85 g of the acid and 15 grams of diluent).

Moreover, when referring to the compositions described herein in terms of weight %, it is understood that in no event shall the weight % of all components, including non-essential components, such as impurities, add to more than 100 weight %. In compositions “consisting essentially of” recited components, such components may add up to 100 weight % of the composition or may add up to less than 100 weight %. Where the components add up to less than 100 weight %, such composition may include some small amounts of a non-essential contaminants or impurities. For example, in one such embodiment, the formulation can contain 2% by weight or less of impurities. In another embodiment, the formulation can contain 1% by weight or less than of impurities. In a further embodiment, the formulation can contain 0.05% by weight or less than of impurities. In other such embodiments, the constituents can form at least 90 wt %, more preferably at least 95 wt %, more preferably at least 99 wt %, more preferably at least 99.5 wt %, most preferably at least 99.9 wt % of the composition, and can include other ingredients that do not material affect the performance of the composition. Otherwise, if no significant non-essential impurity component is present, it is understood that the composition of all essential constituent components will essentially add up to 100 weight %.

The headings employed herein are not intended to be limiting; rather, they are included for organizational purposes only.

### Disclosed and Claimed Bismuth Precursor

In one embodiment, the disclosed and claimed subject matter includes homoleptic precursors of the formula Bi(Ar)₃ where Ar is a neo-pentyl group, a sec-pentyl group and an iso-pentyl group.

In one preferred embodiment, homoleptic precursors of the formula Bi(Ar)₃ is tri(neo-pentyl)bismuth (“BiNp₃”):

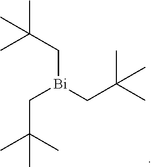

In one embodiment, the disclosed and claimed subject matter includes formulations that include, consist essentially of or consist of tri(neo-pentyl)bismuth (“BiNp₃”).

In one preferred embodiment, homoleptic precursors of the formula Bi(Ar)₃ is tri(sec-pentyl)bismuth.

In one embodiment, the disclosed and claimed subject matter includes formulations that include, consist essentially of or consist of tri(sec-pentyl)bismuth.

In one preferred embodiment, homoleptic precursors of the formula Bi(Ar)₃ is tri(iso-pentyl)bismuth.

In one embodiment, the disclosed and claimed subject matter includes formulations that include, consist essentially of or consist of tri(iso-pentyl)bismuth.

### Method of Use

The disclosed and claimed subject matter further includes the use of homoleptic precursors of the formula Bi(Ar)₃ where Ar is a bulky alkyl group selected from an iso-propyl group, a sec-butyl group, an iso-butyl group, a neo-pentyl group, a sec-pentyl group and an iso-pentyl group to deposit bismuth containing films using any chemical vapor deposition process known to those of skill in the art. As used herein, the term “chemical vapor deposition process” refers to any process wherein a substrate is exposed to one or more volatile precursors, which react and/or decompose on the substrate surface to produce the desired deposition.

In one embodiment, the method includes the use of one or more of the above homoleptic bismuth precursors to deposit bismuth containing films using an atomic layer deposition process (ALD). As used herein, the term “atomic layer deposition process” or ALD refers to a self-limiting (e.g., the amount of film material deposited in each reaction cycle is constant), sequential surface chemistry that deposits films of materials onto substrates of varying compositions. Although the precursors, reagents and sources used herein may be sometimes described as “gaseous,” it is understood that the precursors can be either liquid or solid which are transported with or without an inert gas into the reactor via direct vaporization, bubbling or sublimation. In some case, the vaporized precursors can pass through a plasma generator. The term “reactor” as used herein, includes without limitation, reaction chamber, reaction vessel or deposition chamber.

Chemical vapor deposition processes in which the above homoleptic bismuth precursors can be utilized include, but are not limited to, those used for the manufacture of semiconductor type microelectronic devices such as ALD and plasma enhanced ALD (PEALD). This, in one embodiment, for example, the metal-containing film is deposited using an ALD process. In another embodiment, for example, the metal-containing film is deposited using a plasma enhanced ALD (PEALD) process.

Suitable substrates on which the above homoleptic bismuth precursors can be deposited are not particularly limited and vary depending on the final use intended. For example, the substrate may be chosen from oxides such as HfO₂ based materials, TiO₂ based materials, ZrO₂ based materials, rare earth oxide-based materials, ternary oxide-based materials, etc. or from nitride-based films. Other substrates may include solid substrates such as metal substrates (for example, Au, Pd, Rh, Ru, W, Al, Ni, Ti, Co, Pt and metal silicides (e.g., TiSi₂, CoSi₂, and NiSi₂); metal nitride containing substrates (e.g., TaN, TiN, WN, TaCN, TiCN, TaSiN, and TiSiN); semiconductor materials (e.g., Si, SiGe, GaAs, InP, diamond, GaN, and SiC); insulators (e.g., SiO₂, Si₃N₄, SiON, HfO₂, Ta₂O₅, ZrO₂, TiO₂, Al₂O₃, and barium strontium titanate); combinations thereof. Preferred substrates include HfO₂ based materials, TiO₂ based materials, ZrO₂ based materials, rare earth oxide-based materials, and silicon oxide-based substrates.

In such deposition methods and processes an oxidizing agent can be utilized. The oxidizing agent is typically introduced in gaseous form. Examples of suitable oxidizing agents include, but are not limited to, oxygen gas, water vapor, ozone, oxygen plasma, or mixtures thereof.

The deposition methods and processes may also involve one or more purge gases. The purge gas, which is used to purge away unconsumed reactants and/or reaction byproducts, is an inert gas that does not react with the precursors. Exemplary purge gases include, but are not limited to, argon (Ar), nitrogen (N₂), helium (He), neon, and mixtures thereof. For example, a purge gas such as Ar is supplied into the reactor at a flow rate ranging from about 10 to about 2000 seem for about 0.1 to 10000 seconds, thereby purging the unreacted material and any byproduct that may remain in the reactor.

The deposition methods and processes require that energy be applied to the above homoleptic bismuth precursors, oxidizing agent, other precursors or combination thereof to induce reaction and to form the metal-containing film or coating on the substrate. Such energy can be provided by, but not limited to, thermal, plasma, pulsed plasma, helicon plasma, high density plasma, inductively coupled plasma, X-ray, e-beam, photon, remote plasma methods, and combinations thereof. In some processes, a secondary RF frequency source can be used to modify the plasma characteristics at the substrate surface. When utilizing plasma, the plasma-generated process may include a direct plasma-generated process in which plasma is directly generated in the reactor, or alternatively a remote plasma-generated process in which plasma is generated outside of the reactor and supplied into the reactor.

When utilized in such deposition methods and processes the above homoleptic bismuth precursors may be delivered to the reaction chamber such as an ALD reactor in a variety of ways. In some instances, a liquid delivery system may be utilized. In other instances, a combined liquid delivery and flash vaporization process unit may be employed, such as, for example, the turbo vaporizer manufactured by MSP Corporation of Shoreview, MN, to enable low volatility materials to be volumetrically delivered, which leads to reproducible transport and deposition without thermal decomposition of the precursor. BiNp₃ can be effectively used as source reagents via direct liquid injection (DLI) to provide a vapor stream of these metal precursors into an ALD reactor.

When used in these deposition methods and processes, formulations of the above homoleptic bismuth precursors can be mixed with and can include hydrocarbon solvents which are particularly desirable due to their ability to be dried to sub-ppm levels of water. Exemplary hydrocarbon solvents that can be used in the precursors include, but are not limited to, toluene, mesitylene, cumene (isopropylbenzene), p-cymene (4-isopropyl toluene), 1,3-diisopropylbenzene, octane, dodecane, 1,2,4-trimethylcyclohexane, n-butylcyclohexane and decahydronaphthalene (decalin). The disclosed and claimed precursors can also be stored and used in stainless steel containers. In certain embodiments, the hydrocarbon solvent is a high boiling point solvent or has a boiling point of 100 degrees Celsius or greater. The disclosed and claimed precursors can also be mixed with other suitable metal precursors, and the mixture used to deliver both metals simultaneously for the growth of a binary metal-containing films.

A flow of argon and/or other gas may be employed as a carrier gas to help deliver a vapor containing the above homoleptic bismuth precursors to the reaction chamber during the precursor pulsing. When delivering the above homoleptic bismuth precursors, the reaction chamber process pressure is between 1 and 50 torr, preferably between 5 and 20 torr.

Substrate temperature can be an important process variable in the deposition of high-quality metal-containing films. Typical substrate temperatures range from about 150° C. to about 550° C. Higher temperatures can promote higher film growth rates.

In view of the forgoing, those skilled in the art will recognize that the disclosed and claimed subject matter further includes the use of the above homoleptic bismuth precursors in chemical vapor deposition processes as follows.

In one embodiment, the disclosed and claimed subject matter includes a method for forming a bismuth-containing film on at least one surface of a substrate that includes the steps of:
a. providing the substrate with the at least one surface in a reaction vessel;
b. forming a bismuth-containing film on the at least one surface by a thermal chemical vapor deposition (CVD) or atomic layer deposition (ALD) process using one of the above homoleptic bismuth precursors as a metal source compound for the deposition process.
   In a further aspect of this embodiment, the method includes introducing at least one reactant into the reaction vessel. In a further aspect of this embodiment, the method includes introducing at least one reactant into the reaction vessel where the at least one reactant is selected from the group of water, diatomic oxygen, oxygen plasma, ozone, NO, N₂O, NO₂, carbon monoxide, carbon dioxide and combinations thereof. In another aspect of this embodiment, the method includes introducing at least one reactant into the reaction vessel where the at least one reactant is selected from the group of ammonia, hydrazine, monoalkylhydrazine, dialkylhydrazine, nitrogen, nitrogen/hydrogen, ammonia plasma, nitrogen plasma, nitrogen/hydrogen plasma, and combinations thereof. In another aspect of this embodiment, the method includes introducing at least one reactant into the reaction vessel where the at least one reactant is selected from the group hydrogen, hydrogen plasma, a mixture of hydrogen and helium, a mixture of hydrogen and argon, hydrogen/helium plasma, hydrogen/argon plasma, boron-containing compounds, silicon-containing compounds and combinations thereof.

In one embodiment, the disclosed and claimed subject matter includes a method of forming a bismuth-containing film via a cyclic chemical vapor deposition (CCVD) process at temperatures higher than 300° C. that includes the steps of:
a. providing a substrate in a reaction vessel;
b. introducing into the reaction vessel one of the above homoleptic bismuth precursors and a source gas;
c. purging the reaction vessel with a purge gas;
d. sequentially repeating steps b through c until a desired thickness of the bismuth-containing film is obtained.
   In a further aspect of this embodiment, the source gas is one or more of an oxygen-containing source gas selected from water, diatomic oxygen, oxygen plasma, ozone, NO, N₂O, NO₂, carbon monoxide, carbon dioxide and combinations thereof. In another aspect of this embodiment, the source gas is one or more of a nitrogen-containing source gas selected from ammonia, hydrazine, monoalkylhydrazine, dialkylhydrazine, nitrogen, nitrogen/hydrogen, ammonia plasma, nitrogen plasma, nitrogen/hydrogen plasma and mixture thereof. In a further aspect of this embodiment, the purge gas is selected from argon, nitrogen, helium, neon, and combinations thereof. In a further aspect of this embodiment, the method further includes applying energy to the homoleptic bismuth precursor, the source gas, the substrate, and combinations thereof, wherein the energy is one or more of thermal, plasma, pulsed plasma, helicon plasma, high density plasma, inductively coupled plasma, X-ray, e-beam, photon, remote plasma methods and combinations thereof. In a further aspect of this embodiment, step b of the method further includes introducing into the reaction vessel the homoleptic bismuth precursor using a stream of carrier gas to deliver a vapor of the precursor into the reaction vessel. In a further aspect of this embodiment, step b of the method further includes use of a solvent medium comprising one or more of toluene, mesitylene, isopropylbenzene, 4-isopropyl toluene, 1,3-diisopropylbenzene, octane, dodecane, 1,2,4-trimethylcyclohexane, n-butylcyclohexane, and decahydronaphthalene and combinations thereof.

In one embodiment, the disclosed and claimed subject matter includes a method of forming a bismuth-containing film via a thermal atomic layer deposition (ALD) process or thermal ALD-like process that includes the steps of:
a. providing a substrate in a reaction vessel;
b. introducing into the reaction vessel one of the above homoleptic bismuth precursors;
c. purging the reaction vessel with a first purge gas;
d. introducing into the reaction vessel a source gas;
e. purging the reaction vessel with a second purge gas;
f. sequentially repeating steps b through e until a desired thickness of the bismuth-containing film is obtained.
   In a further aspect of this embodiment, the source gas is one or more of an oxygen-containing source gas selected from water, diatomic oxygen, ozone, NO, N₂O, NO₂, carbon monoxide, carbon dioxide and combinations thereof. In another aspect of this embodiment, the source gas is one or more of a nitrogen-containing source gas selected from ammonia, hydrazine, monoalkylhydrazine, dialkylhydrazine, nitrogen, nitrogen/hydrogen, ammonia plasma, nitrogen plasma, nitrogen/hydrogen plasma and mixture thereof. In a further aspect of this embodiment, the first and second purge gases are each independently selected from one or more of argon, nitrogen, helium, neon, and combinations thereof. In a further aspect of this embodiment, the method further includes applying energy to the one or more precursor, the source gas, the substrate, and combinations thereof, wherein the energy is one or more of thermal, plasma, pulsed plasma, helicon plasma, high density plasma, inductively coupled plasma, X-ray, e-beam, photon, remote plasma methods and combinations thereof. In a further aspect of this embodiment, step b of the method further includes introducing into the reaction vessel the precursor using a stream of carrier gas to deliver a vapor of the precursor into the reaction vessel. In a further aspect of this embodiment, step b of the method further includes use of a solvent medium comprising one or more of toluene, mesitylene, isopropylbenzene, 4-isopropyl toluene, 1,3-diisopropylbenzene, octane, dodecane, 1,2,4-trimethylcyclohexane, n-butylcyclohexane, and decahydronaphthalene and combinations thereof.

In one aspect of this disclosure, one of the above homoleptic bismuth precursors may be used to co-deposit multi-component oxide films. Multi-component oxide film may further include an oxide of one or more elements selected from magnesium, calcium, strontium, barium, aluminum, gallium, indium, titanium, zirconium, hafnium, vanadium, niobium, tantalum, molybdenum, tungsten, tellurium and antimony.

In one embodiment, the disclosed and claimed subject matter includes a method of forming a bismuth-containing multi-component oxide film in a thermal atomic layer deposition (ALD) process or thermal ALD-like process that includes the steps of:
a. providing a substrate in a reaction vessel;
b. introducing into the reaction vessel one of the above homoleptic bismuth precursors;
c. introducing into the reaction vessel one or more of co-precursors comprising an element other than bismuth;
d. purging the reaction vessel with a first purge gas;
e. introducing into the reaction vessel a source gas;
f. purging the reaction vessel with a second purge gas;
g. sequentially repeating steps b through f until a desired thickness of the bismuth-containing multi-component oxide film is obtained.

In another embodiment, the disclosed and claimed subject matter includes a method of forming a bismuth-containing multi-component oxide film in a thermal atomic layer deposition (ALD) process or thermal ALD-like process that includes the steps of:
a. providing a substrate in a reaction vessel;
b. introducing into the reaction vessel one of the above homoleptic bismuth precursors;
c. purging the reaction vessel with a first purge gas;
d. introducing into the reaction vessel a source gas;
e. purging the reaction vessel with a second purge gas;
f. introducing into the reaction vessel one or more of co-precursors including an element other than bismuth;
g. purging the reaction vessel with a third purge gas;
h. introducing into the reaction vessel a source gas;
i. purging the reaction vessel with a fourth purge gas;
j. sequentially repeating steps b through i until a desired thickness of the bismuth-containing multi-component oxide film is obtained.

The examples of the co-precursors include but are not limited to trimethylaluminum, tetrakis(dimethylamino) titanium, tetrakis(ethylmethylamino) zirconium, tetrakis(ethylmethylamino) hafnium and tris-isopropylcyclopentadienyl lanthanum.

### EXAMPLES

Reference will now be made to more specific embodiments of the present disclosure and experimental results that provide support for such embodiments. The examples are given below to more fully illustrate the disclosed and claimed subject matter and should not be construed as limiting the disclosed subject matter in any way.

It will be apparent to those skilled in the art that various modifications and variations can be made in the disclosed subject matter and specific examples provided herein without departing from the spirit or scope of the disclosed subject matter. Thus, it is intended that the disclosed subject matter, including the descriptions provided by the following examples, covers the modifications and variations of the disclosed subject matter that come within the scope of any claims and their equivalents.

### Materials and Methods:

All reactions and manipulations described in the examples were conducted under a nitrogen atmosphere using an inert atmosphere glove box or standard Schlenk techniques. All chemicals were received from Millipore-Sigma.

### Synthesis of Tri(neo-pentyl)bismuth (“Bi(Np)₃”)

BiCl₃ (46.52 g, 116 mmol) was dissolved in 200 mL of THF and cooled to −78° C. Neo-pentyl MgCl (350 mL, 1 M in THF, 350 mmol) was added dropwise via a cannula and the mixture was stirred for 18 h while warming to RT. All volatile components were removed under reduced pressure (1 Torr, 30° C.) to yield a light grey solid. The solid was extracted with portions of pentane (4×200 mL). Each portion of pentane was collected by filtration, combined and then concentrated under reduced pressure (1 Torr) to afford a white solid. The solid was allowed to sublime out tri(neo-pentyl)bismuth at 80° C., 100 mTorr (48 g, 96%).

Analysis: ¹H NMR (C₆D₆, 25° C.): 1.09 (s, 27H), 2.11 (d, 6H).

### Chemical Vapor Deposition of Bismuth-Containing Films Using Bi(Np)₃

Bi(Np)₃ was tested in deposition experiments in order to deposit bismuth-containing thin films. Its deposition process was compared to deposition process using another homoleptic precursor, BiPh₃. BiNp₃ is much more volatile compared to BiPh₃ and required milder container heating to produce enough vapor pressure. The container temperature for BiPh₃ was set high at 160° C. in order to deliver an adequate amount of precursor vapor per pulse, while 85° C. container temperature was sufficient to deliver an adequate amount of precursor vapor per pulse of Bi(Np)₃.

“Bi CVD” experiments were performed using alternating pulses of the precursor and carrier gas (Ar) only. In these experiments no reactant was used to demonstrate feasibility to deposit bismuth-containing films by thermal CVD process. As shown in Table 1, BiNp₃ deposited 1542 Å of bismuth-containing film at 400° C., whereas BiPh₃ deposited negligible amounts of bismuth at this temperature. These results clearly demonstrate a relationship between the number of bismuth-aryl bonds and thermal stability. Due to lower thermal stability Bi(Np)₃ is the preferred precursor for deposition of bismuth-containing films by thermal CVD above 320° C. On the other hand, below 280° C. it is sufficiently thermally stable to enable low temperature ALD of bismuth-containing films, for example bismuth oxide.

TABLE 4

| Deposition Parameter | | BiPh₃ | BiNp₃ |
|---|---|---|---|
| Container Temperature | | 160° C. | 85° C. |
| Bi CVD (Å) | 200° C. | — | 0.2 |
| | 280° C. | 0.45 | 1.24 |
| | 320° C. | — | 1.95 |
| | 400° C. | 0 | 1542.52 |

| | |
|---|---|
| Substrate | ZrO₂ |

It is anticipated that the inventive method could be used in conjunction with deposition tools commonly found at semiconductor manufacturing sites to produce bismuth-containing layers for logic applications and other potential functions.

The foregoing description is intended primarily for purposes of illustration. Although the disclosed and claimed subject matter has been shown and described with respect to an exemplary embodiment thereof, it should be understood by those skilled in the art that the foregoing and various other changes, omissions, and additions in the form and detail thereof may be made therein without departing from the spirit and scope of the disclosed and claimed subject matter.

1. A homoleptic precursor of the formula Bi(Ar)₃ wherein Ar is one of a neo-pentyl group, a sec-pentyl group and an iso-pentyl group.

2. The precursor of claim 1, wherein the homoleptic precursor of the formula Bi(Ar)₃ is tri(neo-pentyl)bismuth:

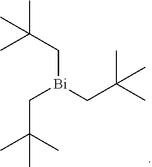

3. The precursor of claim 1, wherein the homoleptic precursor of the formula Bi(Ar)₃ is tri(sec-pentyl)bismuth.

4. The precursor of claim 1, wherein the homoleptic precursor of the formula Bi(Ar)₃ is tri(iso-pentyl)bismuth.

5. A formulation comprising the precursor of claim 1.

6. A method for forming a bismuth-containing film on at least one surface of a substrate comprising:
a. providing the substrate with the at least one surface in a reaction vessel;
b. forming a bismuth-containing film on the at least one surface by chemical vapor deposition (CVD) or an atomic layer deposition (ALD) process using a homoleptic precursor of formula Bi(Ar)₃ where Ar is a bulky alkyl group selected from an iso-propyl group, a sec-butyl group, an iso-butyl group, a neo-pentyl group, a sec-pentyl group and an iso-pentyl group.

7. The method of claim 6, wherein the homoleptic precursor of the formula Bi(Ar)₃ comprises one or more of tri(neo-pentyl)bismuth, tri(sec-pentyl)bismuth and tri(iso-pentyl)bismuth.

8. The method of claim 6, wherein the forming a bismuth-containing film comprises chemical vapor deposition (CVD).

9. The method of claim 6, wherein the forming a bismuth-containing film comprises thermal chemical vapor deposition (CVD).

10. The method of claim 6, wherein the forming a bismuth-containing film comprises cyclic chemical vapor deposition (CCVD).

11. The method of claim 6, wherein the forming a bismuth-containing film comprises atomic layer deposition (ALD).

12. A method for forming a bismuth-containing film on at least one surface of a substrate comprising:
a. providing a substrate in a reaction vessel;
b. introducing into the reaction vessel one or more precursor comprising a homoleptic precursor of formula Bi(Ar)₃ where Ar is a bulky alkyl group selected from iso-propyl, sec-butyl, iso-butyl, neo-pentyl, sec-pentyl and iso-pentyl;
c. purging the reaction vessel with a first purge gas;
d. introducing into the reaction vessel a source gas;
e. purging the reaction vessel with a second purge gas;
f. sequentially repeating steps b through e until a desired thickness of the bismuth-containing film is obtained.

13. The method of claim 12, wherein the homoleptic precursor of the formula Bi(Ar)₃ comprises one or more of tri(neo-pentyl)bismuth, tri(sec-pentyl)bismuth and tri(iso-pentyl)bismuth.

14. The method of claim 12, wherein the source gas is one or more of an oxygen-containing source gas selected from water, diatomic oxygen, oxygen plasma, ozone, NO, N₂O, NO₂, carbon monoxide, carbon dioxide and combinations thereof.

15. The method of claim 12, wherein the source gas is one or more of a nitrogen-containing source gas selected from ammonia, hydrazine, monoalkylhydrazine, dialkylhydrazine, nitrogen, nitrogen/hydrogen, ammonia plasma, nitrogen plasma, nitrogen/hydrogen plasma and mixture thereof.

16. The method of claim 12, wherein the first and second purge gases are each independently selected from one or more of argon, nitrogen, helium, neon, and combinations thereof.

17. The method of claim 12 further comprising applying energy to the one or more precursor, the source gas, the substrate, and combinations thereof, wherein the energy is one or more of thermal, plasma, pulsed plasma, helicon plasma, high density plasma, inductively coupled plasma, X-ray, e-beam, photon, remote plasma and combinations thereof.

18. The method of claim 12, wherein the step b further comprises introducing into the reaction vessel the one or more precursor using a stream of carrier gas to deliver a vapor of the one or more precursor into the reaction vessel.

19. The method of claim 12, wherein step b further comprises use of a solvent medium comprising one or more of toluene, mesitylene, isopropylbenzene, 4-isopropyl toluene, 1,3-diisopropylbenzene, octane, dodecane, 1,2,4-trimethylcyclohexane, n-butylcyclohexane, and decahydronaphthalene and combinations thereof.

20. A precursor supply package, comprising a vessel and the precursor of claim 1, wherein the vessel is adapted to contain and dispense the precursor.
